(19) United States
(12) Patent Application Publication
(10) Pub. No.: US 2011/0284756 A1
(43) Pub. Date: Nov. 24, 2011

(54) DETECTOR FOR DUAL BAND ULTRAVIOLET DETECTION

(75) Inventors: Laddawan R. Miko, Lanham, MD (US); David E. Franz, Pasadena, MD (US); Carl M. Stahle, Severna Park, MD (US); Bing Guan, Bowie, MD (US); Diane E. Pugel, College Park, MD (US); Shahid Aslam, Washington, DC (US)

(73) Assignee: United States of America as repersented by the Administrator of the National Aeronautics and Spac

(21) Appl. No.: 13/092,198

(22) Filed: Apr. 22, 2011

Related U.S. Application Data
(63) Continuation-in-part of application No. 12/176,717, filed on Jul. 21, 2008.

(51) Int. Cl. G01J 1/42; H01L 27/146

(52) U.S. Cl. 250/372; 257/440; 257/E27.134

(57) ABSTRACT

The invention concerns a single detector with two designable wavelengths and bandwidths for ultraviolet detection based on n⁻/n⁺-GaN and AlGaN structures grown over sapphire substrates. The detector has several layers grown over a sapphire substrates, including a buffer layer comprising AlN; a first band-edge comprising Al_{X} Ga_{1-X} N; a second band-edge comprising Al_{Y}Ga_{1-Y} N; a third band-edge comprising Al_{Z} Ga_{1-Z} N. The detector also has ohmic contacts formed on the Al_{X} Ga_{1-X} N band-edge. A bias voltage is applied to the detector through the ohmic contacts so as to select a range of wavelengths in the UV region of interest.

### ORIGIN OF THE INVENTION

This application is a continuation-in-part of application Ser. No. 12/176,717 filed Jul. 21, 2008.

The invention described herein was made by an employee of the United States Government and may be manufactured and used by or for the government for government purposes without payment of any royalties thereon or therefore.

### FIELD OF THE INVENTION

The invention relates generally to barrier detectors formed on gallium nitride and on aluminum gallium nitride for use in ultraviolet detection. The invention further relates to photodiode arrays and more specifically to gallium nitride barrier photodiode arrays for detecting the intensity of ultraviolet rays in a plurality of wave bands.

### BACKGROUND OF THE INVENTION

Ultraviolet (UV) light is an electromagnetic field with wavelength between 200 nm to 400 nm. Generally, UV is classified into three types, including, UVA (320 nm-400 nm), UVB (290 nm-320 nm), and UVC (200 nm-290 nm). There are various and diverse reasons for monitoring UV light. For example, to ascertain the intensity of UV rays since they can be linked to human skin cancer and photoaging, to sense the temperature of a flame, to ascertain the quality of air, to ascertain biosensing functions, and for counter-camouflage imaging. However, for this type of multiband UV monitoring application, multiple detectors and sophisticated optical filters are required.

For the reasons stated above, and for other reasons stated below which will become apparent to those skilled in the art upon reading and understanding the present specification, there is a need in the art for an ultraviolet detector that can measure multiple bands without relying on any external optical filters. There is also a need for improved detector that can be dynamically set to an UV band.

### BRIEF DESCRIPTION OF THE INVENTION

The above-mentioned shortcomings, disadvantages and problems are addressed herein, which will be understood by reading and studying the following specification.

In accordance with a first aspect of the invention, there is provided a barrier detector capable of detecting electromagnetic radiation in the range of 200 nm to 400 nm. This detector has several layers grown over a sapphire substrates, including a buffer layer comprising AlN; a first band-edge comprising Al_{X} Ga_{1-X} N; a second band-edge comprising Al_{Y} Ga_{1-Y} N; a third band-edge comprising Al_{Z} Ga_{1-Z} N. The detector also has ohmic contacts formed on the Al_{X} Ga_{1-X} N band-edge.

In accordance with a second aspect of the invention, there is provided a method for detecting selectable bands in the ultraviolet region with only a single photo detector; the method selects a first detector to detect a first band by applying a first voltage to a bias voltage input node; and selects a second detector to detect a second band by applying a second voltage to the at least one bias voltage input node.

In yet another aspect of the invention, a dual band ultraviolet photo detector has a substrate with N layers, with N being an integer greater than or equal to one, and each of the at least N layers having a barrier bandgap. The apparatus further comprises a first detector formed from the at least N layers capable of detecting a first range of wavelengths and a second detector formed from the at least N layers capable of detecting a second range of wavelengths. The range of wavelengths is selectable through a bias voltage input node coupled to the substrate for selecting the first detector or the second detector.

Apparatus, systems, and methods of varying scope are described herein. In addition to the aspects and advantages described in this summary, further aspects and advantages will become apparent by reference to the drawings and by reading the detailed description that follows.

### BRIEF DESCRIPTION OF THE DRAWINGS

FIG. 1 is a view of a dual band ultraviolet photo detector in accordance to a possible embodiment;

FIG. 2 is a view of a two-color AlGaN ultraviolet detector in accordance to a possible embodiment;

FIG. 3 is a view of the photo response of the two-color UV detector in accordance to a possible embodiment; and

FIG. 4 is a flowchart of a method for selecting bands in the ultraviolet region with only single photo detector accordance to a possible embodiment.

### DETAILED DESCRIPTION OF THE INVENTION

In the following detailed description, reference is made to the accompanying drawings that form a part hereof, and in which is shown by way of illustration specific embodiments which may be practiced. These embodiments are described in sufficient detail to enable those skilled in the art to practice the embodiments, and it is to be understood that other embodiments may be utilized and that logical, mechanical, electrical and other changes may be made without departing from the scope of the embodiments. The following detailed description is, therefore, not to be taken in a limiting sense.

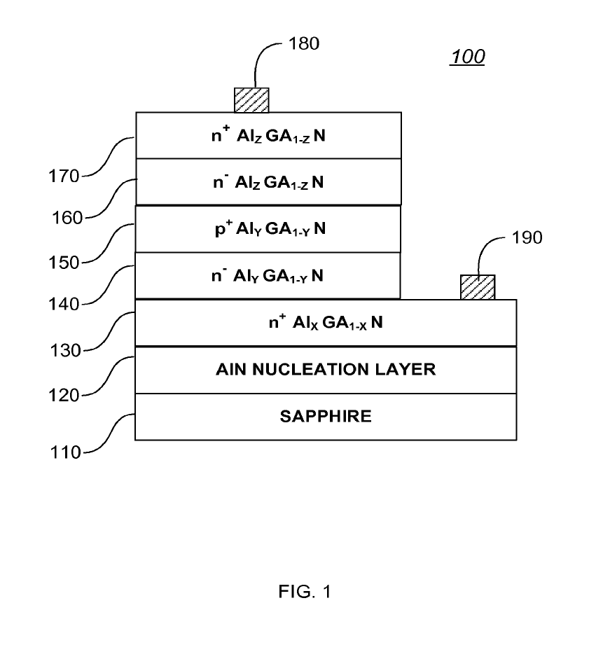

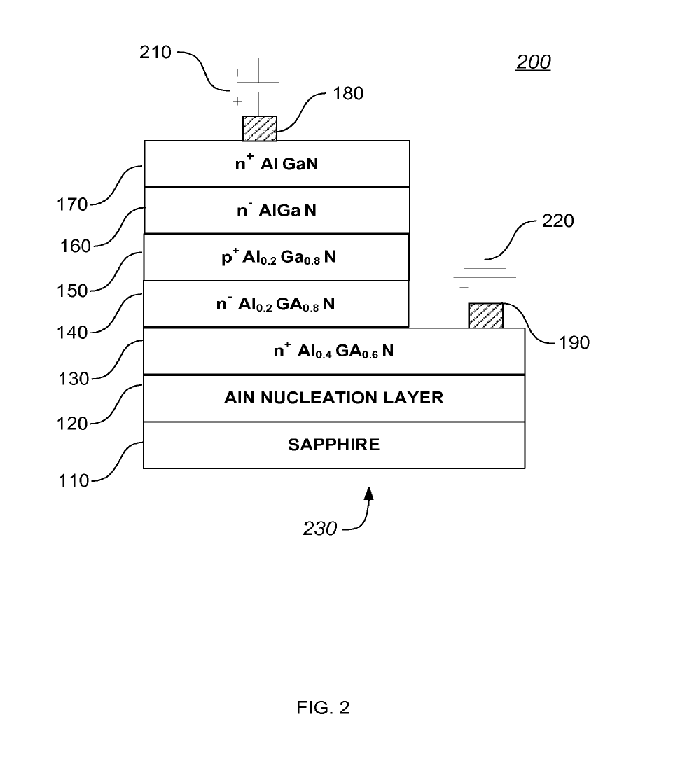

FIG. 1 is the cross-sectional view of the two-color UV detector 100. The structure is designed for back illumination and it contains six AlGaN layers with different doping and Al percentage and two contacts, contact 190 and contact 180. The cut-off wavelength of AlGaN can be tuned by changing the Al percentage from 200 nm to 400 nm. There are three band-edges in structure 100 which corresponds to AlₓGa₁₋ₓN 130, Al_{y}Ga_{1-y}N 140 and 150 and Al_{z}Ga_{1-z}N 160 and 170. X, y, and z should be designed to be X is greater than Y, and Y is greater than Z for back illumination. When photons are injected from backside, the photons will be absorbed at different layer depending on the wavelength of the photons (Wp). If Wp is shorter than the cut-off wavelength of the AlₓGa₁₋ₓN (Wx) photons will mainly be absorbed in n⁺ AlₓGa₁₋ₓN 130 layer. If the wavelength of the photon (Wp) is longer than Wx and shorter than the cut-off wavelength of Al_{y}Gal-yN (Wy) the photons will mainly be absorbed in the n⁻ Al_{y}Ga_{1-y}N 140 layer. If Wp is longer than the Al_{z}Ga_{1-z}N (Wz) layer the photons will go through the detector without absorption. Electrically, the device is actually a back-to-back pin structure along the vertical direction. When contact 180 is biased positively and contact 190 is connected to the ground, the bottom pin is forwardly biased and is like a current variable resistor, whose resistance becomes negligible when the bias on contact 180 is high enough. While the bottom pin the forward biased, the top pin junction is reverse biased and acts as a detector. Since the depletion mainly happens in n⁻ Al_{z}Ga_{1-z}N 160 layer, only the photons absorbed in n⁻ Al_{z}Ga_{1-z}N, i.e., Wy<Wp<Wz will be converted into photon-current. When the bias is applied oppositely, in which contact 180 is biased negatively and contact 190 is connected to ground, the bottom pin is reversely biased and act as an active detector. The depletion region is mainly inn⁻Al_{y}Ga_{1-y}N 140 and the photons with Wx<Wp<Wy can be converted into photo-current. When Wp is less than Wx, all photons will be absorbed in the bottom n⁺AlₓGa₁₋ₓN 130 layer. Most of the photoelectrons will be recombined locally without generating photocurrent. Therefore, by changing the polarity of the bias, the detector can selectively detect two different wavebands: Wy<Wp<Wz when positive bias is applied on contact 190 and Wx<Wp<Wy when negative bias is applied on contact 190. The detector is blind to Wp<Wx(no photocurrent) and Wp>Wz (no absorption). Practically, Wx, Wy, and Wz are tunable between 250 nm to 400 nm. It should be pointed out that the percentage of Al in the p⁺ layer in the center can be any number between Y and Z. As a result, the two detection bands do not have to be continuous. With such a device structure, one single detector can be used to selectively detect designable wavelengths with designable bandwidths by tuning X,Y, and Z. For example, by making the X=0.4, Y=0.2, and Z=0 (See FIG. 2) the detector can detect UVA by applying positive bias on contact 180 and detect UVB by applying negative bias on contact 180. Such a detector does not require any external optical filters.

The invention includes barrier detector 100 capable of detecting electromagnetic radiation in the range of 200 to 400 nm. The detector has several layers grown over sapphire substrates, including a buffer layer comprising AlN; an n+ doped layer comprising Al x Gal-x N 130. The detector further includes ohmic contact 190 formed on the Al x Gal-x N layer and ohmic contact formed on the Al z Gal-z N. In the formula AlxGal-xN, x can range from 0 to 1. As shown in FIG. 2, x is preferably equal to 0.4. The exact value of x is determined by the long wavelength cutoff needed for the particular application. As shown the detector 100 comprising a single crystal substrate, a first band-edge comprising AlX Gal-X N 130; a second band-edge comprising AlY Gal-Y N 140 and 150; a third band-edge comprising AlZ Gal-Z N 160 and 170; and first ohmic contact 180 and second ohmic contact 190.

Generally, the first layer of the ultraviolet detector is a substrate 110 made from sapphire. The substrate 110 functions as a seed for the growth of further layers of the detector as well as a physical support for the detector. Any number of compositions can be used as the substrate, but sapphire is preferred. More preferable is the use of single crystal basal plane sapphire. This is available commercially in single crystal form and serves well as a template for the growth of further layers of the detector. Further, basal plane sapphire is generally transparent to ultraviolet energy.

In order to ease the lattice mismatch between the substrate 110 and the subsequent epitaxial layers, the ultraviolet detector 100 of the invention may also comprise an AlN Nucleation buffer layer 120. Generally, this buffer layer 120 comprises aluminum nitride and is about 10 to 50 nm thick.

A layer of n+ doped Al x Gal-x N is generally deposited over the AlN buffer layer 120. Preferably, this AlxGal-x N layer is single crystal and serves as a substrate for the active AlxGal-x N layer which can be deposited by atomic layer epitaxy.

FIG. 2 is a working example of a two-color AlGaN ultraviolet detector. With such a device structure, one single detector can be used to selectively detect designable wavelengths with designable bandwidths by tuning X, Y, and Z. For example, by making the X=0.4, Y=0.2, and Z=0 the detector can detect UVA by applying positive bias on contact 180 and detect UVB by applying negative bias on contact 180. As shown a first voltage 210 and a second voltage 220 are applied to ohmic contacts 180 and 190. The voltages can range from (−) 5V to (+) 5V.

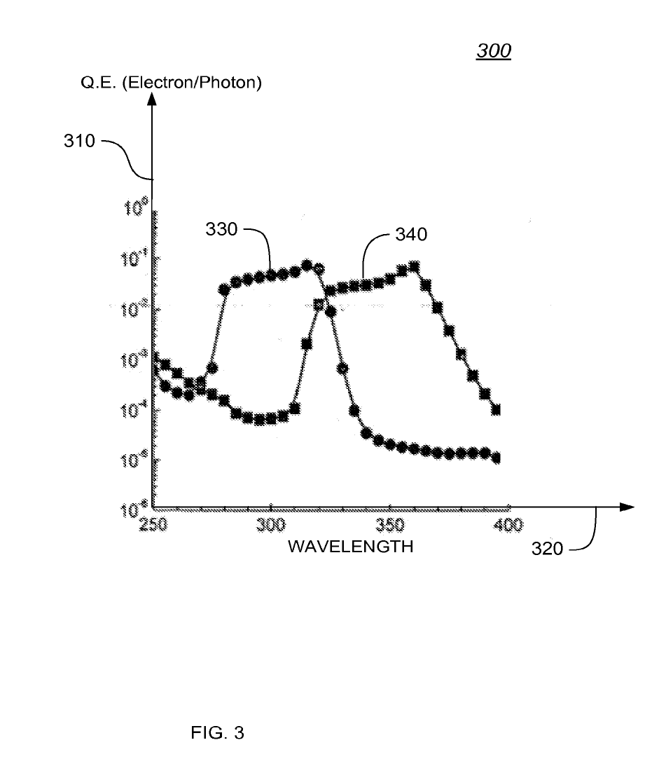

FIG. 3 shows the spectral response 300 of detector 100 when it was positively biased 340 and negatively biased 330. The quantum efficiency 310 or number electron per photon was measured for the ultraviolet range, 200 nm to 400 nm, or wavelength 320. When the detector is negatively biased (−5v) 330 the quantum efficiency is maximum within the UVB range, 290 nm to 320 nm. When the detector is positively biased (+5v) the quantum efficiency is at a maximum at the UVA range, 320 nm to 365 nm.

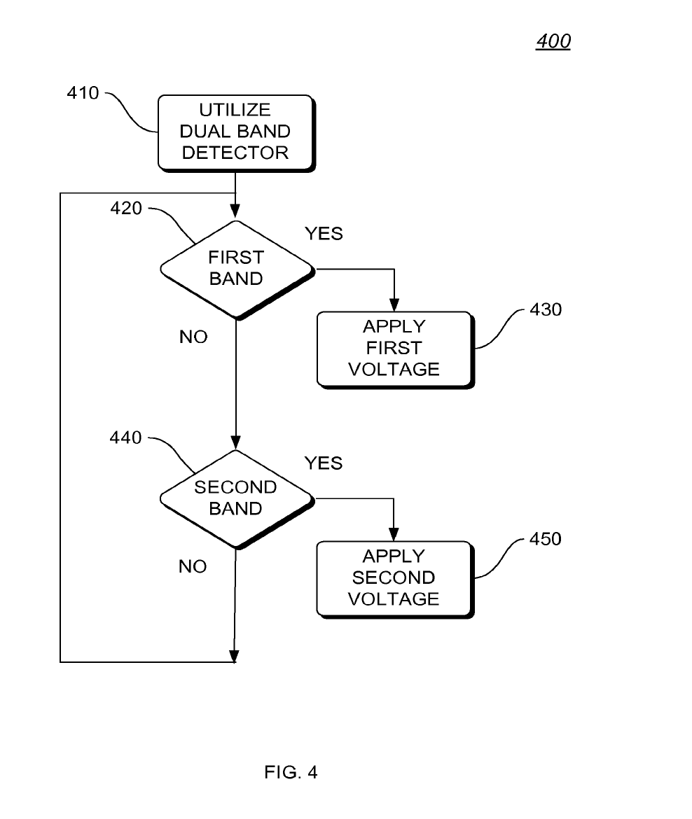

FIG. 4 is a flowchart of method 400 for selecting the operational band of a single ultraviolet detector. Method 400 begins with action 410. In action 410 a dual band photo detector such as described in FIG. 1. is utilized for measuring or monitoring ultraviolet light. Method 400 continuous to action 420 where a determination is made as to the band to monitor in the ultraviolet region. As noted previously the ultraviolet spectrum ranges from 200 nm to 400 nm. Additionally, as noted earlier the UV region can be quantized or categorized to different bands. The well-known bands are UVA, UVB, and UVC. If a first band is desired then control passes to action 430 where the detector such as detector 100 can apply a bias voltage such as −5v. A negatively bias voltage as shown in FIG. 3 would cause a dual band detector (x=0.4, Y=0.2, and Z=0) to select the UVB band (290 nm to 320 nm). When a first band is not selected control passes to action 440 for further processing.

In action 440, a determination is made as to whether a second band is desired. When the determination is yes control passes to action 450 for further processing. In action 450 a second voltage is applied to the detector to select a band other than the first. If a second band is not desired than control returns to the beginning of action 420.

### CONCLUSION

A dual band photo detector is described. A technical effect of the dual band photo detector is a single detector for two designable wavelengths with designable bandwidths in UV without the need for optical filters. As a result, a very small UV monitoring package can be fabricated. Although specific embodiments are illustrated and described herein, it will be appreciated by those of ordinary skill in the art that any arrangement which is calculated to achieve the same purpose may be substituted for the specific embodiments shown.

In particular, one of skill in the art will readily appreciate that the names of the methods and apparatus are not intended to limit embodiments. Furthermore, additional methods and apparatus can be added to the components, functions can be rearranged among the components, and new components to correspond to future enhancements and physical devices used in embodiments can be introduced without departing from the scope of embodiments.

We claim:

1. A dual band ultraviolet photo detector, comprising:
a substrate having at least N layers, with N being an integer greater than or equal to one, and each of the at least N layers having a barrier bandgap;
a first detector formed from the at least N layers capable of detecting a first range of wavelengths across a spectrum ranging from 200 nm to 400 nm;
a second detector formed from the at least N layers capable of detecting a second range of wavelengths across a spectrum ranging from 200 nm to 400 nm;
means for selecting a selectable cut-off wavelength; and
at least one bias voltage input node coupled to the substrate for selecting the first detector or the second detector; wherein the dual band ultraviolet photo detector comprises an AlGaN photodiode array with a said selectable cut-off wavelength determined by adjusting a variable Al percentage in the array.

2. The dual band ultraviolet photo detector of claim 1, wherein the at least N layers is one or more n⁺ Al_{X}Ga_{1-X}N, n⁺ Al_{Z}Ga_{1-Z}N, n⁻ Al_{Y}Ga_{1-Y}N, n⁻ Al_{Z}Ga_{1-Z}N, p⁺ Al_{Y} Ga_{1-Y} N.

3. The dual band ultraviolet photo detector of claim 2, wherein the first range of wavelengths and the second range of wavelengths could be continuous by setting the Al y percentage in the p⁺ Al_{Y}Ga_{1-Y}N layer.

4. The dual band ultraviolet photo detector of claim 3, wherein the bias voltage is either biased positively or biased negatively.

5. The dual band ultraviolet photo detector of claim 4, wherein a positively biased voltage selects the first detector.

6. The dual band ultraviolet photo detector of claim 5, wherein a negatively biased voltage selects the second detector.

7. A method for detecting selectable bands in the ultraviolet region with only a single photo detector, the method comprising:
utilizing a dual band ultraviolet photo detector having at least one bias voltage input node coupled to a substrate, wherein the substrate has at least N layers, with N being an integer greater than or equal to one, and each of the at least N layers having a barrier bandgap;
means for selecting a selectable cut-off wavelength;
selecting a said cut-off wavelength determined by adjusting a variable Al percentage in the detector;
selecting a first detector to detect a first band across a spectrum ranging from 200 nm to 400 nm by applying a first voltage to the at least one bias voltage input node; and
selecting a second detector to detect a second band across a spectrum ranging from 200 nm to 400 nm by applying a second voltage to the at least one bias voltage input node.

8. The method claim 7, wherein the at least N layers is one or more n⁺ Al_{X}Ga_{1-X}N, n⁺ Al_{Z}Ga_{1-Z}N, n⁻ Al_{Y}Ga_{1-Y}N, n⁻ Al_{Z}Ga_{1-Z}N, p⁺ Al_{Y}Ga_{1-Y}.

9. The method of claim 8, wherein the first band and the second band could be continuous by setting the Al_{Y} percentage in the p⁺Al_{Y}Ga_{1-Y}N layer.

10. The method of claim 9, wherein the bias voltage is either biased positively or biased negatively.

11. The method of claim 10, wherein a positively biased voltage selects the first detector.

12. The method of claim 11, wherein a negatively biased voltage selects the second detector.

13. A photo detector capable of detecting electromagnetic radiation in a range of 200 nm to 400 nm, said photo detector comprising several layers grown over a substrate; said layers sequentially comprising:
a buffer layer comprising AlN;
a first band-edge comprising Al_{X} Ga_{1-X}N;
a second band-edge comprising Al_{Y}Ga_{1-Y} N;
a third band-edge comprising Al_{Z} Ga_{1-Z}N;
a first ohmic contact formed on the first band-edge, wherein the first ohmic contact is capable of receiving a voltage;
a second ohmic contact formed on the third band edge, wherein the second ohmic contact is capable of receiving a voltage;
means for selecting a selectable cut-off wavelength;
wherein X is greater than Y and Y is greater than Z;
wherein a voltage difference between the first ohmic contact and the second ohmic contact can cause the detector to detect a selected band of the electromagnetic radiation across said range between 200 nm-400 nm with a said selectable cut-off wavelength determined by adjusting a variable Al percentage in the substrate.

14. The photo detector of claim 13, wherein the first band-edge comprises n⁺ Al_{X}Ga_{1-X}N; wherein the second band edge comprises n⁻ Al_{Y}Ga_{1-Y}N and p⁺ Al_{Y}Ga_{1-Y} N, wherein the third band-edge comprises n⁺ Al_{Z} Ga_{1-Z}N and n⁻Al_{Z}Ga_{1-Z}N.

15. The photo detector of claim 14, wherein the first band-edge and the second band-edge could be continuous by setting the Al_{Y} percentage in the p⁺ Al_{Y}Ga_{1-Y}N layer.

16. The photo detector of claim 15, wherein voltage difference is either biased positively or biased negatively.

17. The photo detector of claim 16, wherein a positively biased voltage causes the detector to detect a selected first band of the electromagnetic radiation.

18. The photo detector of claim 17, wherein a negatively biased voltage causes the detector to detect a second band of the electromagnetic radiation.
